(19) United States
(12) Patent Application Publication
(10) Pub. No.: US 2024/0262078 A1
(43) Pub. Date: Aug. 8, 2024

(54) DISPLAY DEVICE AND METHOD OF MANUFACTURING THE SAME

(71) Applicant: Samsung Display Co., LTD., Yongin-si (KR)

(72) Inventors: JI-HOON KIM, Yongin-si (KR); EUNMI SEO, Yongin-si (KR); MINKYOUNG JUNG, Yongin-si (KR); SANG-IL PARK, Yongin-si (KR); SUNGGUK AN, Yongin-si (KR); Junghun LEE, Yongin-si (KR)

(21) Appl. No.: 18/388,829

(22) Filed: Nov. 11, 2023

(30) Foreign Application Priority Data
Feb. 3, 2023 (KR) 10-2023-0014655

(51) Int. Cl. B32B 7/12; B32B 27/06; B32B 37/12; H05K 5/03

(52) U.S. Cl. CPC B32B 7/12; B32B 27/06; B32B 37/12; H05K 5/03; B32B 2307/54; B32B 2307/558; B32B 2307/7376; B32B 2307/748; B32B 2457/20

(57) ABSTRACT

A display device includes a display panel, a functional layer disposed on the display panel, where the functional layer includes at least one selected from an optical layer and an impact absorbing layer, a window disposed on the functional layer, and an adhesive layer disposed between the functional layer and the window. The adhesive layer has a thermal decomposition starting temperature of about 300° C. or higher and a thermal decomposition peak temperature of about 350° C. or higher, where the thermal decomposition peak temperature is defined as a temperature at which an amount of weight loss or gas generation caused by the thermal decomposition is maximized.

This application claims priority to Korean Patent Application No. 10-2023-0014655, filed on Feb. 3, 2023, and all the benefits accruing therefrom under 35 U.S.C. § 119, the content of which in its entirety is herein incorporated by reference.

### BACKGROUND

### 1. Field

The present disclosure herein relates to a display device including an adhesive layer disposed between a display panel and a window and a method of manufacturing the same.

### 2. Description of the Related Art

A display device provides information to users by displaying various images on a display screen. In general, a display device displays information within an allocated screen. Recently, flexible display devices including a flexible display panel, which is foldable or bendable, are being developed. Unlike rigid display devices, flexible display devices are foldable, rollable, and bendable. Flexible display devices deformable into various shapes may be portable regardless of the sizes of existing display screens, thereby enhancing user convenience. It is desired for a deformable flexible display device to maintain the reliability and stability of members constituting a display device according to changes in shape.

### SUMMARY

The present disclosure provides a display device which is easily folded and unfolded and has improved manufacturing reliability, and a method of manufacturing the display device.

An embodiment of the invention provides a display device including: a display panel; a functional layer disposed on the display panel, where the functional layer includes at least one selected from an optical layer and an impact absorbing layer; a window disposed on the functional layer; and an adhesive layer disposed between the functional layer and the window, where the adhesive layer has a thermal decomposition starting temperature of about 300° C. or higher and a thermal decomposition peak temperature of about 350° C. or higher, where the thermal decomposition peak temperature is defined as a temperature at which an amount of weight loss or gas generation caused by thermal decomposition is maximized.

In an embodiment, an edge of the adhesive layer, an edge of the functional layer, and an edge of the display panel may be aligned with each other.

In an embodiment, on a plane perpendicular to a thickness direction, an area of the adhesive layer may be greater than an area of the window.

In an embodiment, a first storage modulus of the adhesive layer at 60° C. may be in a range of about 10 kilopascals (KPa) to about 50 KPa.

In an embodiment, a second storage modulus of the adhesive layer at a temperature in a range of about 150° C. to about 200° C. may be about 0.7 times or less the first storage modulus.

In an embodiment, the adhesive layer may have a thickness in a range of about 25 micrometers (μm) to about 75 μm.

In an embodiment, the functional layer may include the optical layer, and the adhesive layer may function as the optical layer.

In an embodiment, the adhesive layer may include at least one selected from an epoxy-based resin, a urethane-based resin, an acrylic resin, and a siloxane-based resin.

In an embodiment, the display device may be divided into a folding region foldable with respect to a folding axis extending in one direction and a non-folding region adjacent to the folding region.

In an embodiment, the display device may further include a protective adhesive layer disposed on the window; and a protective layer disposed on the protective adhesive layer.

In an embodiment, on a cross section parallel to a thickness direction, an edge of the window may be disposed further inward than an edge of the protective adhesive layer.

In an embodiment of the invention, A method of manufacturing a display device includes: preparing a preliminary display device assembly including a preliminary display panel, a preliminary functional layer disposed on the preliminary display panel, a preliminary adhesive layer disposed on the preliminary functional layer, and a preliminary release film disposed on the preliminary adhesive layer; forming a display device assembly including a display panel, a functional layer disposed on the display panel, an adhesive layer disposed on the functional layer, and a release film disposed on the adhesive layer by irradiating the preliminary display device with laser from therebelow or thereabove; and forming a display device by removing the release film and providing a window on the adhesive layer, where the preliminary functional layer includes at least one selected from a preliminary optical layer and a preliminary impact absorbing layer, the preliminary adhesive layer may have a thermal decomposition starting temperature of about 300° C. or higher and a thermal decomposition peak temperature of about 350° C. or higher, and the thermal decomposition peak temperature is defined as a temperature at which an amount of weight loss or gas generation caused by thermal decomposition is maximized.

In an embodiment, an edge region of each of the preliminary display panel, the preliminary functional layer, and the preliminary adhesive layer may be removed through laser irradiation.

In an embodiment, wherein on a cross section parallel to a thickness direction, an edge of the adhesive layer, an edge of the functional layer, and an edge of the display panel may be aligned with each other.

In an embodiment, the preliminary display device assembly may further include a preliminary panel protection film disposed below the preliminary display panel.

In an embodiment, the laser may be radiated from below the preliminary panel protection film.

In an embodiment, the preliminary adhesive layer may include at least one selected from an epoxy-based resin, a urethane-based resin, an acrylic resin, and a siloxane-based resin.

In an embodiment, a first storage modulus of the preliminary adhesive layer at 60° C. may be in a range of about 10 KPa to about 50 KPa.

In an embodiment, a second storage modulus of the preliminary adhesive layer at a temperature in a range of about 150° C. to about 200° C. may be about 0.7 times or less the first storage modulus.

In an embodiment, the adhesive layer may have a thickness in a range of about 25 μm to about 75 μm.

### BRIEF DESCRIPTION OF THE DRAWINGS

The above and other features of the invention will become more apparent by describing in further detail embodiments thereof with reference to the accompanying drawings, in which:

FIG. 1A is a perspective view illustrating a display device according to an embodiment;

FIG. 1B is a perspective view illustrating the display device according to an embodiment illustrated in FIG. 1A in an in-folded state;

FIG. 1C is a perspective view illustrating the display device according to an embodiment illustrated in FIG. 1A in an out-folded state;

FIG. 2 is an exploded perspective view illustrating a display device according to an embodiment;

FIG. 3 is a cross-sectional view taken along line I-I′ of FIG. 2;

FIG. 4 is an enlarged cross-sectional view illustrating a region AA′ of FIG. 3;

FIG. 5 is a plan view illustrating a portion of a display device according to an embodiment;

FIG. 6 is a flowchart illustrating a method of manufacturing a display device according to an embodiment;

FIG. 7 is a view schematically illustrating an operation of manufacturing a display device according to an embodiment;

FIG. 8 is a view schematically illustrating an operation of manufacturing a display device according to an embodiment;

FIG. 9 is a view schematically illustrating an operation of manufacturing a display device according to an embodiment;

FIG. 10 is a view schematically illustrating an operation of manufacturing a display device according to an embodiment; and

FIG. 11 is a view schematically illustrating an operation of manufacturing a display device according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Like reference numerals or symbols refer to like elements throughout. In the drawings, the thickness, the ratio, and the dimension of the elements are exaggerated for effective description of the technical contents.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the present disclosure. The singular forms include the plural forms as well, unless the context clearly indicates otherwise.

The terms such as “below”, “lower”, “above”, “upper” and the like, may be used herein for the description to describe one element's relationship to another element illustrated in the figures. It will be understood that the terms have a relative concept and are described on the basis of the orientation depicted in the figures.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a display device and a method of manufacturing the display device according to embodiments of the invention will be described with reference to the accompanying drawings.

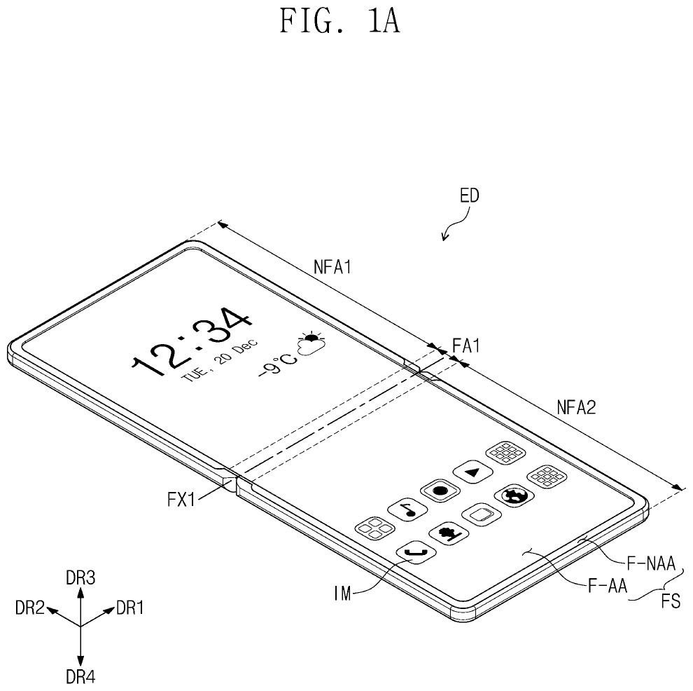

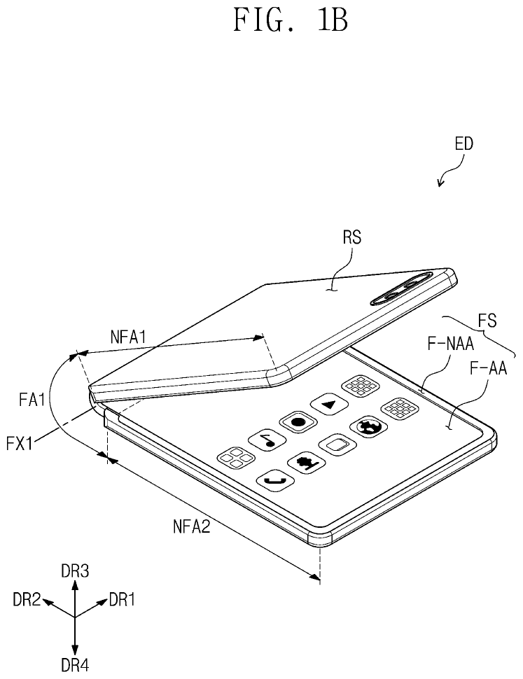

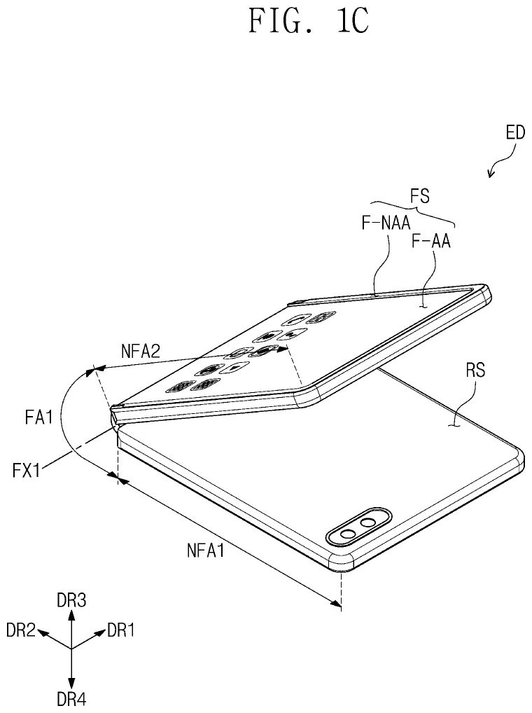

FIG. TA is a perspective view illustrating a display device according to an embodiment. FIG. 1B is a perspective view illustrating the display device illustrated in FIG. TA in an in-folded state. FIG. 1C is a perspective view illustrating the display device illustrated in FIG. TA in an out-folded state.

A display device ED according to an embodiment may be a device activated in response to an electrical signal. In an embodiment, for example, the display device ED may be a mobile phone, a tablet computer, a car navigation system, a game console, a personal computer, a laptop computer, a monitor, or a wearable device, but an embodiment of the invention is not limited thereto. In FIG. TA, an embodiment where the display device ED is a mobile phone is illustrated as an example.

In FIG. TA and the following drawings, first to fourth direction axes DR1, DR2, DR3, and DR4 are illustrated, and the directions indicated by the first to fourth direction axes DR1, DR2, DR3, and DR4 illustrated herein may have a relative concept and may thus be changed to other directions. In addition, the directions indicated by the first to fourth direction axes DR1, DR2, DR3, and DR4 may be referred to as first to fourth directions, respectively, and may thus be denoted as the same reference numerals or symbols.

In this specification, the first direction DR1 and the second direction DR2 may be orthogonal to each other, and the third direction axis DR3 and the fourth direction DR4 may each be a normal direction of a plane defined by the first direction DR1 and the second direction DR2. The fourth direction axis DR4 may be a direction opposite to the third direction DR3. In this specification, a ‘plane’ may be the plane defined by the first direction DR1 and the second direction DR2, and a ‘cross section’ may be the cross section perpendicular to the plane defined by the first direction DR1 and the second direction DR2 and parallel to the third direction DR3. A thickness direction of the display device ED may be parallel to the third direction DR3 which is the normal direction of the plane defined by the first direction DR1 and the second direction DR2.

Referring to FIGS. 1A to 1C, the display device ED according to an embodiment may include a display surface FS parallel to the plane defined by the first direction DR1 and the second direction DR2. The display device ED may provide an image IM to users through the display surface FS. The display device ED according to an embodiment may display, in the third direction DR3, the image IM on the display surface FS parallel to the plane defined by the first direction axis DR1 and the second direction DR2.

In this specification, a front surface (or upper surface) and a rear surface (or lower surface) of each member are defined based on a direction in which the image IM is displayed. In this specification, a direction in which the image IM is displayed is parallel to the third direction DR3, and a direction of the fourth direction DR4 is defined as the direction which is opposed to a direction of the third direction axis DR3. In addition, in this specification, an upper portion (or above) and a lower portion (or below) may be defined on the basis of the third direction DR3. The upper portion (or above) is defined as the direction parallel to a direction in which the image IM is displayed, and the lower portion (or below) is defined as the direction opposed to a direction in which the image IM is displayed. That is, the upper portion (or above) may be parallel to the third direction DR3, and the lower portion (or below) may be defined as the direction parallel to the fourth direction DR4.

The display device ED according to an embodiment may detect an external input applied from the outside. The external input may include various types of inputs provided from the outside of the display device ED. In an embodiment, for example, the external input may include not only touch by a part of the user's body such as the user's hand but also an external input (for example, hovering) applied while approaching the display device ED or being adjacent within a predetermined distance to the display device ED. In addition, the external input may have various forms such as force, pressure, temperature, light, or the like.

The display surface FS of the display device ED may include an active region F-AA and a peripheral region F-NAA. The active region F-AA may be a region activated in response to an electrical signal. The display device ED may display the image IM through the active region F-AA. Also, various types of external inputs may be detected in the active region F-AA. The peripheral region F-NAA may be adjacent to the active region F-AA. The peripheral region F-NAA may have a predetermined color. In an embodiment, the peripheral region F-NAA may surround the active region F-AA. Accordingly, a shape of the active region F-AA may be substantially defined by the peripheral region F-NAA. However, this is merely an example, and alternatively, the peripheral region F-NAA may be disposed adjacent to only one side of the active region F-AA, or may be omitted. The display device ED according to an embodiment may include active regions having various shapes but is not limited to any one embodiment.

The display device ED may be divided into a folding region FA1 and non-folding regions NFA1 and NFA2 adjacent to the folding region FA1. The display device ED may include a plurality of non-folding regions NFA1 and NFA2. The display device ED according to an embodiment may include a first non-folding region NFA1 and a second non-folding region NFA2 with the folding region FA1 therebetween. FIGS. 1A to 1C illustrate an embodiment where the display device ED includes a single folding region FA1, but an embodiment of the invention is not limited thereto. Alternatively, three or more folding regions may be defined in the display device ED.

Referring to FIGS. 1A to 1C, the display device ED according to an embodiment may be folded (or foldable) with respect to a folding axis FX1. The folding axis FX1 may be an imaginary axis extending in the first direction DR1 and be parallel to a short-side direction of the display device ED. On the display surface FS, the folding axis FX1 may extend along the first direction DR1. Alternatively, the folding axis FX1 may be parallel to a long-side direction of the display device ED.

The folding region FA1 may be folded with respect to the folding axis FX1. The non-folding regions NFA1 and NFA2 may be disposed adjacent to the folding region FA1 while sandwiching the folding region FA1. In the second direction DR2, the non-folding regions NFA1 and NFA2 may be spaced apart from each other with the folding region FA1 therebetween. In an embodiment, for example, the first non-folding region NFA1 may be disposed on one side of the folding region FA1 along the second direction DR2, and the second non-folding region NFA2 may be disposed on the other side of the folding region FA1 along the second direction DR2.

Referring to FIG. 1B, the display device ED may be folded with respect to the folding axis FX1 and be changed into an in-folded state where in the display surface FS, one region overlapping the first non-folding region NFA1 and the other region overlapping the second non-folding region NFA2 face each other. However, an embodiment of the invention is not limited thereto, and the display device ED according to an embodiment may be folded with respect to a plurality of folding axes, and may be folded so that portions of the display surface FS face each other. The number of folding axes and the number of non-folding regions corresponding thereto are not particularly limited. A rear surface RS of the display device ED may be visible to users in a state where the display device ED is in-folded. In an embodiment, for example, the rear surface RS may function as a second display surface on which an image or video is displayed.

Referring to FIG. 1C, the display device ED may be folded with respect to the folding axis FX1 and be changed into an out-folded state where in the rear surface RS, one region overlapping the first non-folding region NFA1 and the other region overlapping the second non-folding region NFA2 face each other. However, an embodiment of the invention is not limited thereto, and the display device ED according to an embodiment may be folded with respect to a plurality of folding axes, and may be folded so that portions of the rear surface RS face each other.

Although not illustrated, an electronic module region (not illustrated) may be defined in the active region F-AA or the rear surface RS. Various electronic module regions (not illustrated) may be disposed in the electronic module region. In an embodiment, for example, the electronic module may include at least one of a camera, a speaker, a light detection sensor, or a heat detection sensor.

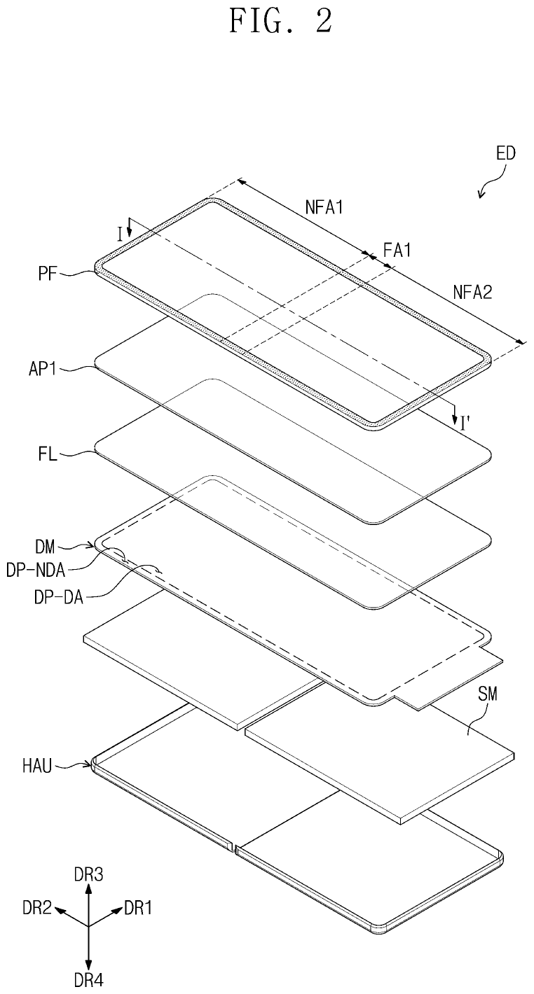

FIG. 2 is an exploded perspective view illustrating a display device according to an embodiment. Referring to FIG. 2, an embodiment of a display device ED may include a display module DM, a functional layer FL disposed on the display module DM, an adhesive layer AP1 disposed on the functional layer FL, and a protective member PF disposed on the adhesive layer AP1. In addition, the display device ED may further include a lower module SM and a housing HAU disposed below the display module DM.

The protective member PF and the housing HAU may be coupled to each other to form the exterior of the display device ED. The protective member PF may transmit an image provided from the display module DM therethrough, and protect components disposed therebelow against external impacts.

The adhesive layer AP1 may be optically transparent. The adhesive layer AP1 may bond the functional layer FL and the protective member PF. The adhesive layer AP1 may include a pressure sensitive adhesive (PSA). In an embodiment, the adhesive layer AP1 may include at least one selected from an epoxy-based resin, a urethane-based resin, an acrylic resin, and a siloxane-based resin. The adhesive layer AP1 will be described later in greater detail.

The display module DM may display an image in response to an electrical signal and transmit/receive information about an external input. The display module DM may be divided into a display region DP-DA and a non-display region DP-NDA. The display region DP-DA may be defined as a region where an image provided from the display module DM is displayed.

The non-display region DP-NDA may be adjacent to the display region DP-DA. In an embodiment, for example, the non-display region DP-NDA may surround the display region DP-DA. However, this is merely an example, and the non-display region DP-NDA may be defined as having various shapes and is not limited to any one embodiment. The display region DP-DA of the display module DM may correspond to at least a portion of the active region F-AA (see FIG. 1A).

The housing HAU may include a material having relatively high rigidity. In an embodiment, for example, the housing HAU may include a plurality of frames and/or plates composed of glass, plastic, or metal. The housing HAU may provide a predetermined accommodation space, and the display module DM and the lower module SM may be accommodated inside the accommodation space.

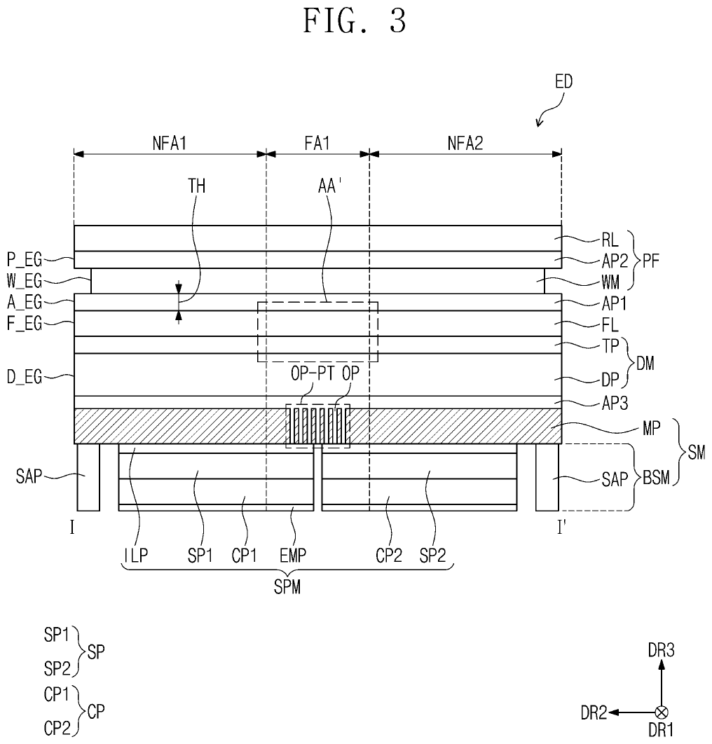

FIG. 3 is a cross-sectional view taken along line I-I′ of FIG. 2. FIG. 3 may be a cross-sectional view illustrating a display device ED according to an embodiment. For convenience of illustration and description, in FIG. 3, a housing HAU is omitted, and the components such as a lower module SM, a display module DM, a functional layer FL, an adhesive layer AP1, and a protective member PF are illustrated.

The lower module SM may include a support plate MP and a lower support member BSM. The support plate MP may be disposed below the display module DM. The support plate MP may include a metal material or a polymer material. In an embodiment, for example, the support plate MP may include or be formed of stainless steel, aluminum, or an alloy thereof. Alternatively, the support plate MP may include or be formed of a polymer material. A plurality of openings OP may be defined in the support plate MP. The support plate MP may include opening patterns OP-PT with the plurality of openings OP defined therein. The opening patterns OP-PT may be formed or provided in (or to overlap) the folding region FA1.

The lower support member BSM may include a support member SPM and a filling part SAP. The support member SPM may overlap most of regions of the display module DM. The filling part SAP may be disposed outside the support member SPM and overlap an outer periphery of the display module DM.

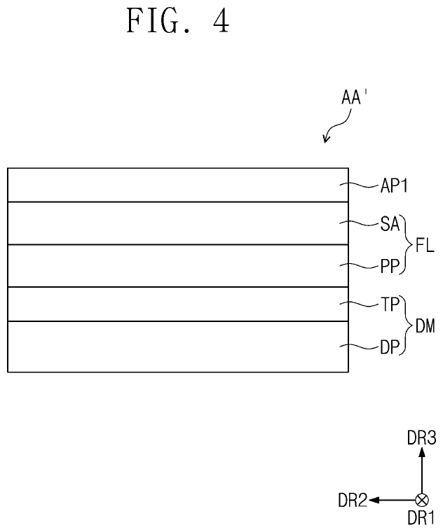

The support member SPM may include at least one selected from a support layer SP, a cushion layer CP, a shielding layer EMP, and an interlayer-bonding layer ILP. In embodiments, a configuration of the support member SPM is not limited to what is illustrated in FIG. 4, etc., and may vary or be variously modified according to the size and shape of the display device ED or the operating characteristics of the display device ED, or the like. In an alternative embodiment, for example, some of the support layer SP, the cushion layer CP, the shielding layer EMP, and the interlayer-bonding layer ILP may be omitted, a stacking order thereof may be changed to another order different from that illustrated in FIG. 4, or additional components, in addition to the illustrated components, may be further included.

The support layer SP may include a metal material or a polymer material. The support layer SP may be disposed below the support plate MP. In an embodiment, for example, the support layer SP may be a thin-metal substrate. The support layer SP may include a first sub-support layer SP1 and a second sub-support layer SP2 which are spaced apart from each other in the second direction DR2. The first sub-support layer SP1 and the second sub-support layer SP2 may be spaced apart from each other in a region corresponding to the folding axis FX1 (see FIG. 1A). Since the support layer SP is provided as the first sub-support layer SP1 and the second sub-support layer SP2 which are spaced apart from each other in the folding region FAT, the folding characteristic of the display device ED may be improved.

The cushion layer CP may be disposed under the support layer SP. The cushion layer CP may effectively prevent the support plate MP from being pressed or plastically deformed due to an external impact and force. The cushion layer CP may improve the impact resistance of the display device ED. The cushion layer CP may include an elastomer, etc., such as a sponge, a foam, or a urethane resin. In addition, the cushion layer CP may include or be formed of at least one selected from an acrylic polymer, a urethane-based polymer, a silicone-based polymer, and an Imide-based polymer. However, this is merely an example, and an embodiment of the invention is not limited thereto.

The cushion layer CP may include a first sub-cushion layer CP1 and a second sub-cushion layer CP2 spaced apart from each other in the second direction DR2. The first sub-cushion layer CP1 and the second sub-cushion layer CP2 may be spaced apart from each other in a portion corresponding to the folding axis FX1 (see FIG. 1A). in such an embodiment, since the cushion layer CP is provided as the first sub-cushion layer CP1 and the second sub-cushion layer CP2 which are spaced apart from each other in the folding region FAT, the folding characteristic of the display device ED may be improved.

The shielding layer EMP may be an electromagnetic wave shielding layer or a heat dissipation layer. In addition, the shielding layer EMP may function as a bonding layer. The interlayer-bonding layer ILP may bond the support plate MP and the components of the support member SPM. The interlayer-bonding layer ILP may be provided in a form of a bonding resin layer or an adhesive tape. FIG. 3 illustrates an embodiment where the interlayer-bonding layer ILP is provided as two parts, spaced apart from each other in a region corresponding to the folding axis FX1, but an embodiment of the invention is not limited thereto. Alternatively, the interlayer-bonding layer ILP may be provided as a single layer not spaced apart in a region corresponding to the folding axis FX1.

The filling part SAP may be disposed outside the support layer SP and the cushion layer CP. The filling part SAP may be disposed between the support plate MP and the housing HAU (see FIG. 2). The filling part SAP may fill the space between the support plate MP and the housing HAU (see FIG. 2) and fix the support plate MP.

A lower adhesive layer AP3 may be disposed between the display module DM and the lower module SM. In an embodiment, for example, the lower adhesive layer AP3 may include a typical adhesive agent such as an optically clear adhesive (OCA) and an optical clear adhesive resin (OCR) but is not limited to any one embodiment. Alternatively, the lower adhesive layer AP3 may be omitted.

The display module DM may include a display panel DP and an input-sensing portion TP. The display panel DP may be a light-emitting display panel. In an embodiment, for example, the display panel DP may be an organic light-emitting display panel, an inorganic light-emitting display panel, a micro-light emitting diode (LED) display panel, a micro-OLED display panel, or a nano-LED display panel.

The input-sensing portion TP may be disposed on the display panel DP. In an embodiment, for example, the input-sensing portion TP may be directly disposed on the display panel DP. In this specification, when an element is referred to as being directly disposed on another element, there are no intervening element therebetween. That is, the wording, “an element is ‘directly disposed on’ another element” may mean that an element is ‘in contact with’ the other element or an element is formed directly on the other element.

The input-sensing portion TP may detect an external input, change the detected external input to a predetermined input signal, and provide the input signal to the display panel DP. In an embodiment, for example, the input-sensing portion TP of the display device ED according to an embodiment may be a touch-sensing portion which detects a touch. The input-sensing portion TP may recognize a user's direct touch, a user's indirect touch, a direct touch by an object, or an indirect touch by an object.

The input-sensing portion TP may detect a position or intensity (pressure) of touch applied from the outside. The input-sensing portion TP may have various structures or be formed of various materials, but is not limited to any one embodiment. The input-sensing portion TP may include a plurality of sensing electrodes (not illustrated) for detecting external inputs. The sensing electrodes (not illustrated) may detect external inputs in a capacitive manner. The display panel DP may receive input signals from the input-sensing portion TP and generate images corresponding the input signals.

The functional layer FL may be disposed on the input-sensing portion TP. The functional layer FL may have a single- or multi-layered structure. The functional layer FL may include at least one selected from an optical layer PP and an impact absorbing layer SA. FIG. 4 is an enlarged cross-sectional view illustrating a region AA′ of FIG. 3. Referring to FIG. 4, the functional layer FL may have a multi-layered structure including the optical layer PP and the impact absorbing layer SA. Alternatively, at least one selected from the optical layer PP and the impact absorbing layer SA may be omitted. In such an embodiment, the functional layer FL may have a single-layered structure including the optical layer PP or a single-layered structure including the impact absorbing layer SA. The optical layer PP may be disposed above the display panel DP and control the reflected light of external light on the display panel DP. In an embodiment, for example, the optical layer PP may include a polarizing plate.

Referring back to FIG. 3, the protective member PF may include a window WM, a protective adhesive layer AP2, and a protective layer RL. The window WM may be disposed above the functional layer FL, and the protective layer RL may be disposed above the window WM. The protective adhesive layer AP2 may be disposed between the window WM and the protective layer RL.

The protective layer RL may be a functional layer which protects one surface of the window WM. The protective layer RL may include an anti-fingerprint coating agent, a hard coating agent, and an anti-static agent.

The protective adhesive layer AP2 may bond the window WM and the protective layer RL. The protective adhesive layer AP2 may include a typical adhesive agent such as a pressure sensitive adhesive (PSA), an optically clear adhesive (OCA), and an optical clear resin (OCR) but is not limited to any one embodiment. Alternatively, the protective adhesive layer AP2 may be omitted.

The image IM (see FIG. 1) generated from the display panel DP may pass through the window WM and be provided to users. The window WM may include an optically transparent insulating material. The window WM may be a glass substrate or a polymer substrate. In an embodiment, for example, the window WM may be a tempered glass substrate that has been subjected to reinforcement treatment. In addition, the window WM may include or be formed of polyimide, polyacrylate, polymethylmethacrylate, polycarbonate, polyethylenenaphthalate, polyvinylidene chloride, polyvinylidene difluoride, polystyrene, ethylene vinylalcohol copolymer or a combination thereof. However, this is merely illustrated as an example, and materials included in the window WM are not limited thereto.

The adhesive layer AP1 may be disposed between the functional layer FL and the window WM. The adhesive layer AP1 may be directly disposed on the functional layer FL. In an embodiment where the functional layer FL includes the optical layer PP, the adhesive layer AP1 and the optical layer PP may be integrally provided, that is, a single layer may be provided to function as the adhesive layer AP1 and the optical layer PP. The adhesive layer AP1 may have a thickness TH in a range of about 25 micrometers (μm) to about 75 μm. If the adhesive layer has a thickness of less than about 25 μm, durability may be deteriorated. If the adhesive layer has a thickness of greater than about 75 μm, the thickness of a display device is increased, so that it may not be easy to be repeatedly folded and unfolded. In an embodiment, since the adhesive layer AP1 has a thickness TH in a range of about 25 μm to about 75 μm, it is possible to facilitate the repeated folding and unfolding and exhibit improved durability.

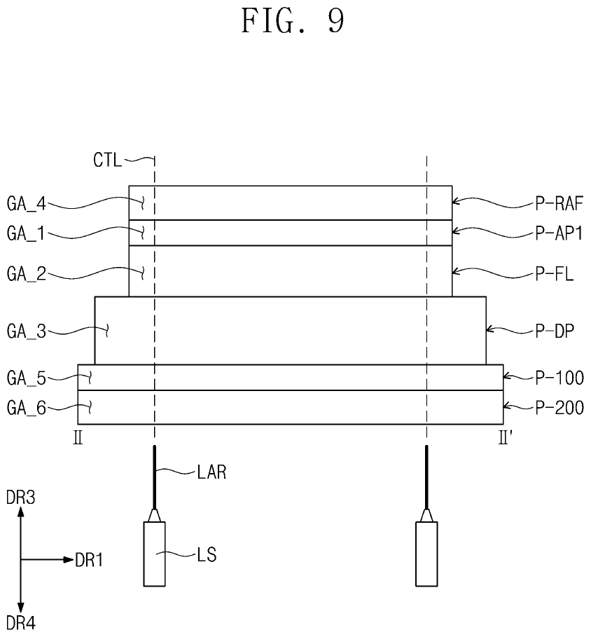

In an embodiment, the adhesive layer AP1 may have a thermal decomposition starting temperature of about 300° C. or higher and a thermal decomposition peak temperature of about 350° C. or higher. In this specification, the thermal decomposition starting temperature and the thermal decomposition peak temperature may be confirmed through thermogravimetric analysis (TGA) or measurement of gas generation caused by a thermal decomposition. The thermal decomposition peak temperature may be defined as the temperature at which the amount of the weight loss or the gas generation caused by the thermal decomposition is maximized. The adhesive layer AP1 having a thermal decomposition starting temperature of about 300° C. or higher and a thermal decomposition peak temperature of about 350° C. or higher may be formed from a preliminary adhesive layer P-AP1 through a later-described method of manufacturing a display device according to an embodiment. The adhesive layer AP1 may be formed by irradiating the preliminary adhesive layer P-AP1 (see FIG. 9) with a laser LAR (see FIG. 9). The adhesive layer AP1 may be formed by removing, with the laser LAR (see FIG. 9), an edge region GA_1 (see FIG. 9) of the preliminary adhesive layer P-AP1 (see FIG. 9).

The preliminary adhesive layer P-AP1 (see FIG. 9) may have a thermal decomposition starting temperature of about 300° C. or higher and a thermal decomposition peak temperature of about 350° C. or higher. The thermal decomposition starting temperature and the thermal decomposition peak temperature of the preliminary adhesive layer P-AP1 (see FIG. 9) may be substantially the same as the thermal decomposition starting temperature and the thermal decomposition peak temperature of the adhesive layer AP1, respectively. In this specification, the phrase “being substantially the same” means not only a case where numerical values are physically the same as each other, but also a case where there is a difference within a margin of error which may generally occur during a process.

If the preliminary adhesive layer provided to form the adhesive layer AP1 has a thermal decomposition starting temperature of less than about 300° C. and a thermal decomposition peak temperature of less than about 350° C., one region irradiated with the laser LAR (see FIG. 9) may be damaged and thus the formed adhesive layer is partially damaged. In an embodiment, since the preliminary adhesive layer P-AP1 (see FIG. 9) provided to form the adhesive layer AP1 may have a thermal decomposition starting temperature of about 300° C. or higher and a thermal decomposition peak temperature of about 350° C. or higher, it is possible to exhibit high thermal stability. Therefore, the adhesive layer AP1 may be formed with improved manufacturing reliability. A method of manufacturing a display device according to an embodiment will be described later in more detail.

According to an embodiment, the storage modulus of the adhesive layer AP1 at 60° C. may be in a range of about 10 kilopascal (KPa) to about 50 KPa. An adhesive layer having a storage modulus of less than about 10 KPa at 60° C. may have poor durability, and an adhesive layer having a storage modulus of greater than about 50 KPa at 60° C. may not be easy to be repeatedly folded and unfolded. In an embodiment of the invention, since the adhesive layer AP1 has a storage modulus in a range of about 10 KPa to about 50 KPa at 60° C., it is possible to exhibit high durability and facilitate the repeated folding and unfolding. Therefore, the display device ED including the adhesive layer AP1 according to an embodiment may exhibit improved reliability.

The storage modulus (hereinafter, referred to as second storage modulus) of the adhesive layer AP1 at a temperature in a range of about 150° C. to about 200° C. may be about 0.7 time or less the storage modulus (hereinafter, referred to as first storage modulus) at 60° C. The storage modulus (hereinafter, referred to as fourth storage modulus) of the preliminary adhesive layer P-AP1 (see FIG. 9) at a temperature in a range of about 150° C. to about 200° C. may be about 0.7 times or less the storage modulus (hereinafter, referred to as third storage modulus) at 60° C. The third storage modulus of the preliminary adhesive layer P-APT (see FIG. 9) at 60° C. may be in a range of about 10 KPa to about 50 KPa. When irradiated with the laser LAR (see FIG. 9), the preliminary adhesive layer P-AP1 (see FIG. 9) having a fourth storage modulus, which is about 0.7 times or less the third storage modulus, at a temperature of about 150° C. to about 200° C. may exhibit high stability. Therefore, the adhesive layer AP1 with improved manufacturing reliability may be formed from the preliminary adhesive layer P-AP1 (see FIG. 9) having the fourth storage modulus, which is about 0.7 times or less the third storage modulus, at a temperature in a range of about 150° C. to about 200° C.

The first storage modulus of the adhesive layer AP1 may be substantially the same as the third storage modulus of the preliminary adhesive layer P-APT (see FIG. 9). In addition, the second storage modulus of the adhesive layer APT may be substantially the same as the fourth storage modulus of the preliminary adhesive layer P-AP1 (see FIG. 9). The first and third storage moduli may be storage moduli at 60° C., and the second and fourth storage moduli may be storage moduli at a temperature in a range of about 150° C. to about 200° C.

Referring to FIG. 3, a first edge A_EG of the adhesive layer AP1, a second edge F_EG of the functional layer FL, and a third edge D_EG of the display panel DP may overlap each other. The first edge A_EG of the adhesive layer AP1, the second edge F_EG of the functional layer FL, and the third edge D_EG of the display panel DP may each be parallel to the third direction DR3. The first edge A_EG of the adhesive layer AP1, the second edge F_EG of the functional layer FL, and the third edge D_EG of the display panel DP may be aligned with each other in the third direction DR3. The edges A_EG, F_EG, and D_EG of the adhesive layer AP1, the functional layer FL, and the display panel DP, which are formed by being irradiated with the laser LAR (see FIG. 9), may be parallel to each other on a straight line, that is, be on a same plane.

In a case where an edge of an adhesive layer is not parallel to an edge of a functional layer and the area of an adhesive layer is smaller than the area of a functional layer on a plane, the edge of the adhesive layer is disposed further inward than the edge of the functional layer. In this case, foreign materials may be introduced into the space where the adhesive layer is not disposed, thereby causing damage to components such as a window and a display panel. In the display device ED according to an embodiment, the first edge A_EG of the adhesive layer AP1 may be parallel to the second edge F_EG of the functional layer FL, and the area of the adhesive layer AP1 may be substantially the same as the area of the functional layer FL on a plane. In such an embodiment, the display device ED including the adhesive layer AP1 may effectively prevent damage of components caused by the introduction of foreign materials. Thus, the display device ED including the adhesive layer AP1 according to an embodiment may exhibit improved reliability.

A fourth edge W_EG of the window WM may be spaced apart from the first edge A_EG of the adhesive layer AP1 in the second direction DR2. The fourth edge W_EG of the window WM may be disposed further inward than the first edge A_EG of the adhesive layer AP1. The fourth edge W_EG of the window WM may be more adjacent to the folding region FA1 than the first edge A_EG of the adhesive layer AP1.

The fourth edge W_EG of the window WM may be disposed further inward than a fifth edge P_EG of the protective adhesive layer AP2. In an embodiment, for example, the fifth edge P_EG of the protective adhesive layer AP2 may be parallel to the first edge A_EG of the adhesive layer AP1 on a straight line. However, an embodiment of the invention is not limited thereto, and alternatively, the fifth edge P_EG of the protective adhesive layer AP2 may be disposed further outward than the first edge A_EG of the adhesive layer AP1.

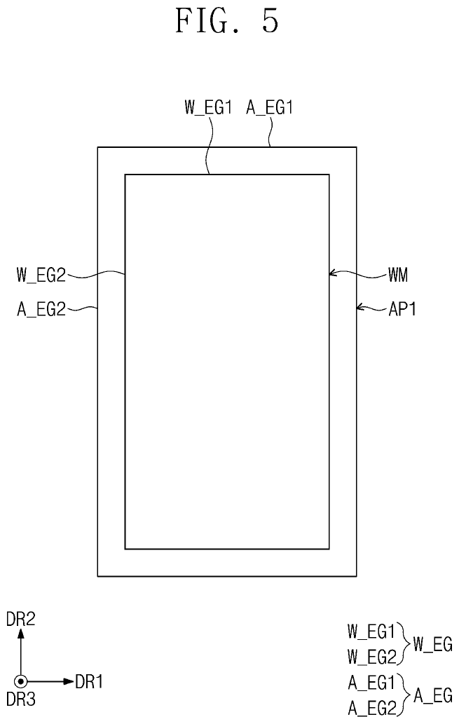

FIG. 5 is a plan view illustrating a window WM and an adhesive layer AP1, and illustrates, for convenience of illustration and description, only some of components.

Referring to FIG. 5, a first area of the adhesive layer AP1 may be greater than a second area of the window WM on a plane. The first area of the adhesive layer AP1 may be substantially the same as a third area of the functional layer FL.

A fourth edge W_EG of the window WM may be disposed further inward than a first edge A_EG of the adhesive layer AP1. FIG. 5 illustrates that the window WM and the adhesive layer AP1 have a rectangular shape, but an embodiment of the invention is not limited thereto.

The fourth edge W_EG of the window WM may include two short-side edges W_EG1 and two long-side edges W_EG2. The first edge A_EG of the adhesive layer AP1 may include two short-side edges A_EG1 and two long-side edges A_EG2. FIG. 5 illustrates that the short-side edges W_EG1 and the long-side edges W_EG2 of the window WM are disposed further inward than the short-side edges A_EG1 and the long-side edges W_EG2 of the adhesive layer AP1, but an embodiment of the invention is not limited thereto. The short-side edges W_EG1 of the window WM may be disposed further inward than the short-side edges A_EG1 of the adhesive layer AP1, and the long-side edges W_EG2 of the window WM may be disposed to overlap the long-side edges A_EG2 of the adhesive layer AP1. Alternatively, the short-side edges W_EG1 of the window WM may be disposed to overlap the short-side edges A_EG1 of the adhesive layer AP1, and the long-side edges W_EG2 of the window WM may be disposed further inward than the long-side edges A_EG2 of the adhesive layer AP1.

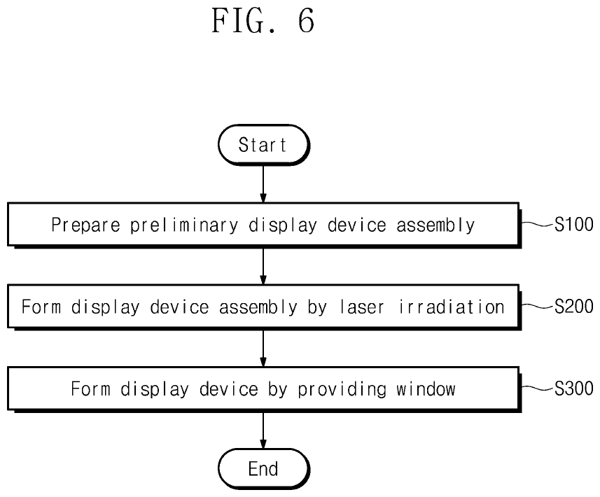

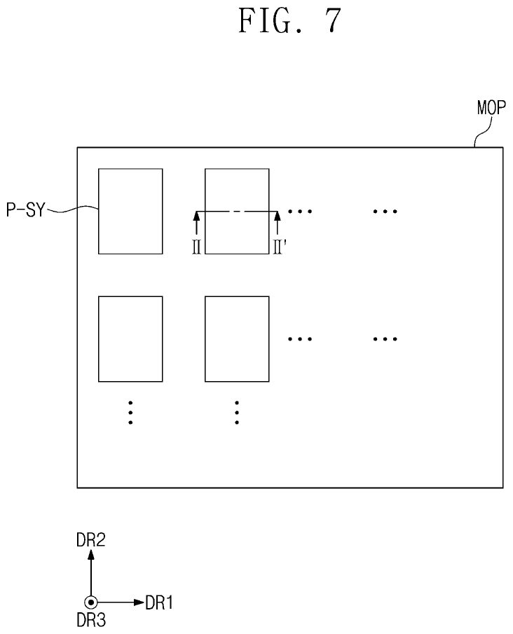

A display device according to an embodiment may be manufactured through a method of manufacturing a display device according to an embodiment. FIG. 6 is a flowchart illustrating a method of manufacturing a display device according to an embodiment. FIGS. 7 to 11 are views schematically illustrating operations of manufacturing a display device according to an embodiment. In descriptions of FIGS. 6 to 11, any repetitive detailed description of the same or like contents in FIGS. 6 to 11 as those described above with the references to FIGS. 1A to 5 will be omitted or simplified, and the following description will be mainly focused on the differences.

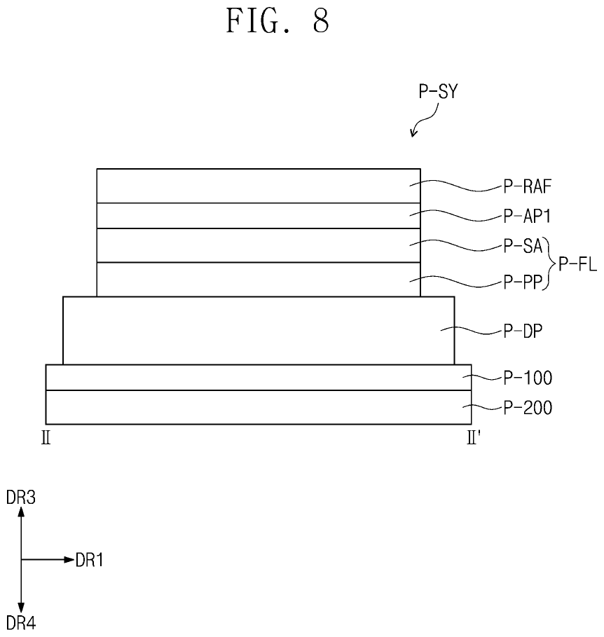

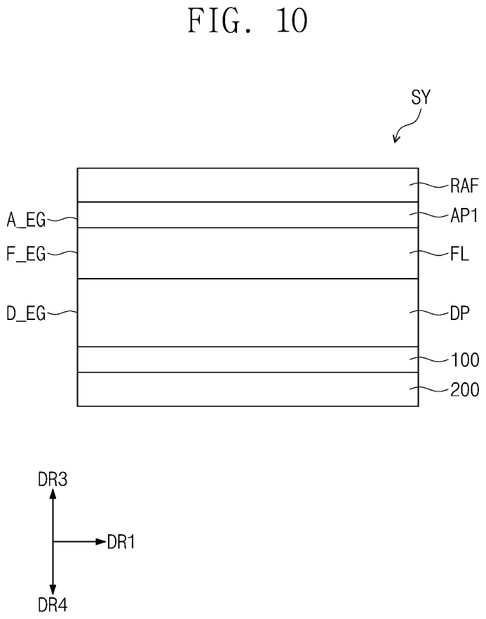

Referring to FIG. 6, the method of manufacturing the display device according to an embodiment may include preparing a preliminary display device assembly (S100), forming a display device assembly by laser irradiation (S200), and forming a display device by providing a window (S300). A laser LAR (see FIG. 9) may be provided or radiated from below or above a preliminary display device assembly P-SY. A display device assembly SY (see FIG. 10) may be formed from the preliminary display device assembly P-SY (see FIGS. 7 and 8), and the display device ED (see FIG. 2) may be formed from the display device assembly SY (see FIG. 10).

FIG. 7 is a plan view illustrating a display substrate MOP including a preliminary display device assembly P-SY. The display substrate MOP may be a mother substrate including a plurality of preliminary display device assemblies P-SY. FIG. 7 schematically illustrates that the display substrate MOP includes four preliminary display device assemblies P-SY, and the four preliminary display device assemblies P-SY are arranged in two rows and two columns. However, the number and arrangement of the preliminary display device assemblies P-SY included in the display substrate MOP are not limited thereto.

FIG. 8 is a cross-sectional view taken along line II-II′ of FIG. 7, and may be a cross-sectional view illustrating a preliminary display device assembly P-SY. The preliminary display device assembly P-SY may include a preliminary display panel P-DP, a preliminary functional layer P-FL disposed on the preliminary display panel P-DP, a preliminary adhesive layer P-AP1 disposed on the preliminary functional layer P-FL, and a preliminary release film P-RAF disposed on the preliminary adhesive layer P-AP1. Although not illustrated, the preliminary display device assembly P-SY may further include the input-sensing portion TP (see FIG. 3) directly disposed on the preliminary display panel P-DP.

Referring to FIG. 8, the preliminary functional layer P-FL may include a preliminary optical layer P-PP and a preliminary impact absorbing layer P-SA. However, this is merely illustrated as an example, and either of the preliminary optical layer P-PP or the preliminary impact absorbing layer P-SA may be omitted.

The preliminary adhesive layer P-AP1 may include at least one selected from an epoxy-based resin, a urethane-based resin, an acrylic resin, and a siloxane-based resin. The preliminary release film P-RAF may be directly disposed on the preliminary adhesive layer P-AP1. One surface, of the preliminary release film P-RAF, which is in contact with the preliminary adhesive layer P-AP1, may have been subjected to release treatment.

The preliminary display device assembly P-SY may further include a preliminary panel protection film P-200 disposed below the preliminary display panel P-DP and a preliminary film adhesive layer P-100 disposed between the preliminary display panel P-DP and the preliminary panel protection film P-200. The preliminary panel protection film P-200 may be a protection film which is provided to prevent the preliminary display panel P-DP from being damaged during the manufacturing of the display device ED.

FIG. 9 is a view illustrating an operation of providing laser LAR to a preliminary display device assembly P-SY. A laser irradiation apparatus LS may irradiate the preliminary display device assembly P-SY with the laser LAR. Referring to FIG. 9, the laser irradiation apparatus LS may be disposed below a preliminary panel protection film P-200, and the laser LAR may be provided from below the preliminary panel protection film P-200.

An edge region GA_1 of a preliminary adhesive layer P-AP1, an edge region GA_2 of a preliminary functional layer P-FL, and an edge region GA_3 of a preliminary display panel P-DP may be removed by being irradiated with the laser LAR. The edge region GA_1 of the preliminary adhesive layer P-AP1, the edge region GA_2 of the preliminary functional layer P-FL, and the edge region GA_3 of the preliminary display panel P-DP are removed, and a display device assembly SY including an adhesive layer AP1, a functional layer FL, and a display panel DP may be formed. The edge region GA_1 of the preliminary adhesive layer P-AP1, the edge region GA_2 of the preliminary functional layer P-FL, and the edge region GA_3 of the preliminary display panel P-DP, which are disposed outside the cutting line CTL, may be removed on the basis of a predetermined cutting line CTL which is appropriately designed or predetermined for the desired size and/or shape.

Also, an edge region GA_4 of a preliminary release film P-RAF, an edge region GA_5 of a preliminary film adhesive layer P-100, and an edge region GA_6 of a preliminary panel protection film P-200 may be removed by being irradiated with the laser LAR. The edge region GA_4 of the preliminary release film P-RAF, the edge region GA_5 of the preliminary film adhesive layer P-100, and the edge region GA_6 of the preliminary panel protection film P-200 are removed, and a release film RAF, a film adhesive layer 100, and a panel protection film 200 may be formed. The display device assembly SY may include the release film RAF disposed on the adhesive layer AP1, the film adhesive layer 100 disposed under the display panel DP, and the panel protection film 200 disposed under the film adhesive layer 100.

In an embodiment, the preliminary adhesive layer P-AP1 may have a thermal decomposition starting temperature of about 300° C. or higher and a thermal decomposition peak temperature of about 350° C. or higher. The preliminary adhesive layer P-AP1, having a thermal decomposition starting temperature of about 300° C. or higher and a thermal decomposition peak temperature of about 350° C. or higher, may exhibit high stability when being irradiated with the laser LAR. Therefore, the adhesive layer AP1 formed from the preliminary adhesive layer P-AP1 may exhibit high manufacturing reliability. The first to third edges A_EG, F_EG, and D_EG, of the respective adhesive layer AP1, functional layer FL, and display panel DP, which are formed by being irradiated with the laser LAR may overlap each other or on a same line or plane. The first edge A_EG of the adhesive layer AP1, the second edge F_EG of the functional layer FL, and the third edge D_EG of the display panel DP may be parallel to each other on a straight line.

Also, the release film RAF, disposed on the adhesive layer AP1 which is formed from the preliminary adhesive layer P-AP1 having a thermal decomposition starting temperature of about 300° C. or higher and a thermal decomposition peak temperature of about 350° C. or higher, may be easily removed. The release film RAF may be removed without damage to the adhesive layer AP1. The release film RAF may be a heavy-peeling release film. The heavy-peeling release film may be required to have relatively higher peeling force than a light-peeling release film. The adhesive layer AP1 according to an embodiment is formed from the preliminary adhesive layer P-AP1 having a thermal decomposition starting temperature of about 300° C. or higher and a thermal decomposition peak temperature of about 350° C. or higher, and thus even when the release film RAF is provided as a heavy-peeling release film, it is possible to be easily peeled off from the adhesive layer AP1.

In a case where the laser is irradiated from below the preliminary adhesive layer having a thermal decomposition starting temperature of less than about 300° C. and a thermal decomposition peak temperature of less than about 350° C., a region irradiated with the laser and a peripheral region therearound may be damaged. Therefore, a portion of the adhesive layer may be adhered to the release film, and thus the release film may not be easily removed. It is understood that the preliminary adhesive layer having a thermal decomposition starting temperature of less than about 300° C. and a thermal decomposition peak temperature of less than about 350° C. has a relatively low thermal decomposition starting temperature and a relatively low thermal decomposition peak temperature. When the preliminary adhesive layer having a relatively low thermal decomposition starting temperature and a relatively low thermal decomposition peak temperature is disposed above the preliminary display panel, and the preliminary adhesive layer is irradiated with laser by the laser irradiation apparatus disposed below the preliminary display panel, the high-temperature laser causes the preliminary adhesive layer to be damaged. Thus, the release film disposed on the adhesive layer formed from the preliminary adhesive layer may not be effectively removed.

In a state in which the preliminary adhesive layer P-AP1, having a thermal decomposition starting temperature of about 300° C. or higher and a thermal decomposition peak temperature of about 350° C. or higher, is disposed on the preliminary display panel P-DP, the preliminary adhesive layer P-AP1 may exhibit high stability even when irradiated with the high-temperature laser LAR from below the preliminary display panel P-DP. The preliminary adhesive layer P-AP1 according to an embodiment has a thermal decomposition starting temperature of about 300° C. or higher and a thermal decomposition peak temperature of about 350° C. or higher, and thus the adhesive layer AP1 formed from the preliminary adhesive layer P-AP1 may exhibit improved manufacturing reliability.

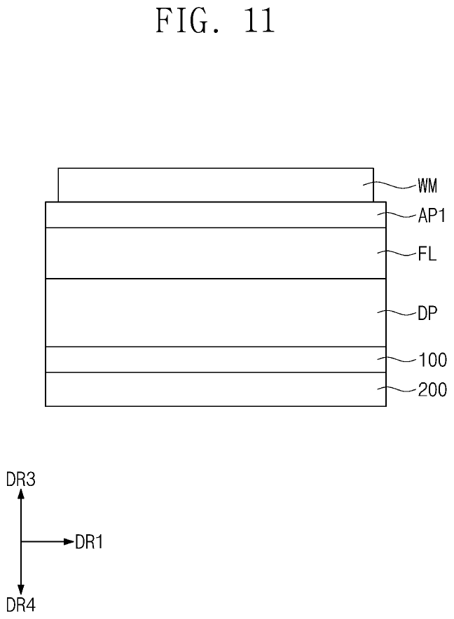

Referring to FIG. 11, a window WM may be provided by removing the release film RAF (see FIG. 10) disposed on an adhesive layer AP1. After the window WM is provided on the adhesive layer AP1, a panel protection film 200 and a film adhesive layer 100 are removed, and the display device ED (see FIG. 3) may be formed.

Table 1 below shows records of a thermal decomposition starting temperature and a thermal decomposition peak temperature of an adhesive layer and evaluation results of peeling property of a release film according to Examples and Comparative Example. Eight samples were respectively prepared for Example 1, Example 2, and Comparative Example, and peeling evaluation parameter was recorded as 8 in Table 1. In Table 1, a failure in peeling of a release film indicates the number of samples in which an adhesive layer was damaged when a release film was peeled off after the adhesive layer was formed by irradiating a preliminary adhesive layer with laser. The thermal decomposition peak temperature and the thermal decomposition starting temperature of the preliminary adhesive layer and the adhesive layer are substantially the same.

TABLE 1

| | | | Comparative |
|---|---|---|---|
| | Example 1 | Example 2 | Example |
| Thermal decomposition | 390 | 400 | 320 |
| peak temperature (° C.) | | | |
| Thermal decomposition | 300 | 300 | 200 |
| starting temperature (° C.) | | | |
| Peeling evaluation | 8 | 8 | 8 |
| parameter | | | |
| Failure in Peeling of | 0 | 0 | 3 |
| Release film | | | |
| Peeling success rate | 100% | 100% | 62.5% |

Referring to Table 1, it may be understood that the adhesive layers according to Examples 1 and 2 each had a thermal decomposition starting temperature of about 300° C. or higher and a thermal decomposition peak temperature of about 350° C. or higher and a failure in peeling of the release film did not occur. That is, it may be confirmed that since the adhesive layers according to Examples 1 and 2 each had a thermal decomposition starting temperature of about 300° C. or higher and a thermal decomposition peak temperature of about 350° C. or higher, the release films were peeled off without damage to the adhesive layers. Therefore, it is considered that in an embodiment, the preliminary adhesive layer having a thermal decomposition starting temperature of about 300° C. or higher and a thermal decomposition peak temperature of about 350° C. or higher and the adhesive layer formed therefrom may exhibit improved manufacturing reliability.

The adhesive layer according to Comparative Example has a thermal decomposition starting temperature of less than about 300° C. and a thermal decomposition peak temperature of less than about 350° C. It may be understood that a failure in peeling of the release film occurred in three out of the eight adhesive layer samples according to Comparative Example. It is considered that the adhesive layer according to Comparative Example had a relatively low thermal decomposition starting temperature and thermal decomposition peak temperature, and thus the release film was not peeled off.

A display device according to an embodiment is manufactured through a method of manufacturing a display device according to an embodiment, and the method of manufacturing the display device according to an embodiment may include forming an adhesive layer by irradiating a preliminary adhesive layer with laser. An edge region of the preliminary adhesive layer is removed and the adhesive layer is formed. The preliminary adhesive layer may have a thermal decomposition starting temperature of about 300° C. or higher and a thermal decomposition peak temperature of about 350° C. or higher, thereby exhibiting high stability even when irradiated with high-temperature laser. Therefore, the adhesive layer formed from the preliminary adhesive layer may exhibit improved manufacturing reliability. The display device according to an embodiment may include the adhesive layer according to an embodiment between a display panel and a window, thereby exhibiting high stability.

A display device according to an embodiment may include an adhesive layer satisfying predetermined thermal decomposition temperature and storage modulus conditions, thereby exhibiting high stability and reliability.

A method of manufacturing a display device according to an embodiment may include forming an adhesive layer from a preliminary adhesive layer satisfying predetermined thermal decomposition temperature and storage modulus conditions, thereby exhibiting improved manufacturing reliability.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel;
a functional layer disposed on the display panel, wherein the functional layer includes at least one selected from an optical layer and an impact absorbing layer;
a window disposed on the functional layer; and
an adhesive layer disposed between the functional layer and the window, wherein the adhesive layer has a thermal decomposition starting temperature of about 300° C. or higher and a thermal decomposition peak temperature of about 350° C. or higher,
wherein the thermal decomposition peak temperature is defined as a temperature at which an amount of weight loss or gas generation caused by thermal decomposition is maximized.

2. The display device of claim 1, wherein an edge of the adhesive layer, an edge of the functional layer, and an edge of the display panel are aligned with each other.

3. The display device of claim 1, wherein on a plane perpendicular to a thickness direction, an area of the adhesive layer is greater than an area of the window.

4. The display device of claim 1, wherein a first storage modulus of the adhesive layer at 60° C. is in a range of about 10 KPa to about 50 KPa.

5. The display device of claim 4, wherein a second storage modulus of the adhesive layer at a temperature in a range of about 150° C. to about 200° C. is about 0.7 times or less the first storage modulus.

6. The display device of claim 1, wherein the adhesive layer has a thickness in a range of about 25 μm to about 75 μm.

7. The display device of claim 1, wherein
the functional layer comprises the optical layer, and
the adhesive layer functions as the optical layer.

8. The display device of claim 1, wherein the adhesive layer comprises at least one selected from an epoxy-based resin, a urethane-based resin, an acrylic resin, and a siloxane-based resin.

9. The display device of claim 1, wherein the display device is divided into a folding region foldable with respect to a folding axis extending in one direction and a non-folding region adjacent to the folding region.

10. The display device of claim 1, further comprising:
a protective adhesive layer disposed on the window; and
a protective layer disposed on the protective adhesive layer.

11. The display device of claim 10, wherein on a cross section parallel to a thickness direction, an edge of the window is disposed further inward than an edge of the protective adhesive layer.

12. A method of manufacturing a display device, the method comprising:
preparing a preliminary display device assembly including a preliminary display panel, a preliminary functional layer disposed on the preliminary display panel, a preliminary adhesive layer disposed on the preliminary functional layer, and a preliminary release film disposed on the preliminary adhesive layer;
forming a display device assembly including a display panel, a functional layer disposed on the display panel, an adhesive layer disposed on the functional layer, and a release film disposed on the adhesive layer by irradiating the preliminary display device with laser from therebelow or thereabove; and
forming a display device by removing the release film and providing a window on the adhesive layer,
wherein the preliminary functional layer includes at least one selected from a preliminary optical layer and a preliminary impact absorbing layer,
the preliminary adhesive layer has a thermal decomposition starting temperature of about 300° C. or higher and a thermal decomposition peak temperature of about 350° C. or higher, and
the thermal decomposition peak temperature is defined as a temperature at which an amount of weight loss or gas generation caused by thermal decomposition is maximized.

13. The method of claim 12, wherein an edge region of each of the preliminary display panel, the preliminary functional layer, and the preliminary adhesive layer is removed through laser irradiation.

14. The method of claim 12, wherein on a cross section parallel to a thickness direction, an edge of the adhesive layer, an edge of the functional layer, and an edge of the display panel are aligned with each other.

15. The method of claim 12, wherein the preliminary display device assembly further comprises a preliminary panel protection film disposed below the preliminary display panel.

16. The method of claim 15, wherein the laser is radiated from below the preliminary panel protection film.

17. The method of claim 12, wherein the preliminary adhesive layer comprises at least one selected from an epoxy-based resin, a urethane-based resin, an acrylic resin, and a siloxane-based resin.

18. The method of claim 12, wherein a first storage modulus of the preliminary adhesive layer at 60° C. is in a range of about 10 KPa to about 50 KPa.

19. The method of claim 18, wherein a second storage modulus of the preliminary adhesive layer at a temperature in a range of about 150° C. to about 200° C. is about 0.7 times or less the first storage modulus.

20. The method of claim 12, wherein the adhesive layer has a thickness in a range of about 25 μm to about 75 μm.
